(19) United States
(12) Patent Application Publication
(10) Pub. No.: US 2025/0386431 A1
(43) Pub. Date: Dec. 18, 2025

(54) WIRING SUBSTRATE AND SEMICONDUCTOR DEVICE

(71) Applicant: SHINKO ELECTRIC INDUSTRIES CO., LTD., Nagano-shi (JP)

(72) Inventor: Rie MIZUTANI, Nagano-shi (JP)

(21) Appl. No.: 19/237,777

(22) Filed: Jun. 13, 2025

(30) Foreign Application Priority Data
Jun. 18, 2024 (JP) 2024-097839

(51) Int. Cl. H05K 1/02; H05K 1/03

(52) U.S. Cl. CPC H05K 1/0298; H05K 1/0373; H05K 2201/0266; H05K 2201/068; H05K 2201/2081

(57) ABSTRACT

A wiring substrate includes a core substrate, a first wiring structure located on an upper surface of the core substrate, and a second wiring structure located on an upper surface of the first wiring structure. The first wiring structure includes a structure in which one or more first wiring layers and one or more first insulating layers are stacked. The second wiring structure includes a structure in which multiple second wiring layers and multiple second insulating layers are stacked. The second wiring structure has a higher wiring density than the first wiring structure. The second insulating layer has a thermal expansion coefficient higher than that of the core substrate and lower than that of the first insulating layer.

### CROSS-REFERENCE TO RELATED APPLICATIONS

This application is based upon and claims the benefit of priority from Japanese Patent Application No. 2024-097839, filed on Jun. 18, 2024, the entire contents of which are incorporated herein by reference.

### BACKGROUND

### 1. Field

This disclosure relates to a wiring substrate, a semiconductor device, and a method for manufacturing a wiring substrate.

### 2. Description of Related Art

A typical wiring substrate, on which electronic components such as semiconductor chips are mounted, includes wiring layers and insulating layers stacked on both upper and lower surfaces of a core substrate by a build-up process in order to increase the density of wiring patterns. In this type of wiring substrate, it has been suggested that a high-density wiring layer including an insulating layer formed by a photosensitive resin be arranged on a low-density wiring layer including an insulating layer formed by a non-photosensitive thermosetting resin. Japanese Laid-Open Patent Publication No. 2014-225632 discloses such a wiring substrate.

### SUMMARY

It is desired to improve the connection reliability between the wiring substrate and electronic components, such as semiconductor chips.

In one general aspect, a wiring substrate includes a core substrate, a first wiring structure located on an upper surface of the core substrate, and a second wiring structure located on an upper surface of the first wiring structure. The first wiring structure includes one or more first wiring layers and one or more first insulating layers. The second wiring structure includes a structure in which multiple second wiring layers and multiple second insulating layers are stacked. The second wiring structure has a wiring density higher than a wiring density of the first wiring structure. The multiple second insulating layers have a thermal expansion coefficient higher than a thermal expansion coefficient of the core substrate and lower than a thermal expansion coefficient of the one or more first insulating layers.

Other features and aspects will be apparent from the following detailed description, the drawings, and the claims.

### BRIEF DESCRIPTION OF THE DRAWINGS

FIG. 1 is a schematic cross-sectional view of a semiconductor device in accordance with an embodiment.

FIG. 2A is a schematic cross-sectional view enlarging part of the semiconductor device illustrated in FIG. 1.

FIG. 2B is a schematic cross-sectional view enlarging a region enclosed by single-dashed lines illustrated in FIG. 2A.

FIGS. 3, 4, 5, 6, 7, 8, 9, 10, 11, 12, and 13 are schematic cross-sectional views illustrating a method for manufacturing the wiring substrate illustrated in FIG. 1.

FIGS. 14A and 14B are schematic cross-sectional views of an example of a conventional semiconductor device.

FIGS. 15A and 15B are schematic cross-sectional views enlarging part of the semiconductor device illustrated in FIG. 1.

FIGS. 16A and 16B are schematic cross-sectional views of a comparative example of the comparative semiconductor device.

FIG. 17 is a graph indicating simulation results of warpage of structures in three examples and one conventional example.

FIG. 18 is a schematic cross-sectional view of a modified example of the semiconductor device.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

An embodiment of the present disclosure will now be described with reference to the accompanying drawings.

The accompanying drawings may not be drawn to scale, and the relative size, proportions, and depiction of elements may be exaggerated for clarity, illustration, and convenience. In the cross-sectional views, hatching lines may not be illustrated or may be replaced by shadings to facilitate understanding of the cross-sectional structures. Unless otherwise specified, a numerical range of “X1 to X2”, which is specified by a lower limit value X1 and an upper limit value X2, refers to a range that is greater than or equal to X1 and less than or equal to X2.

### Overall Structure of Semiconductor Device 1

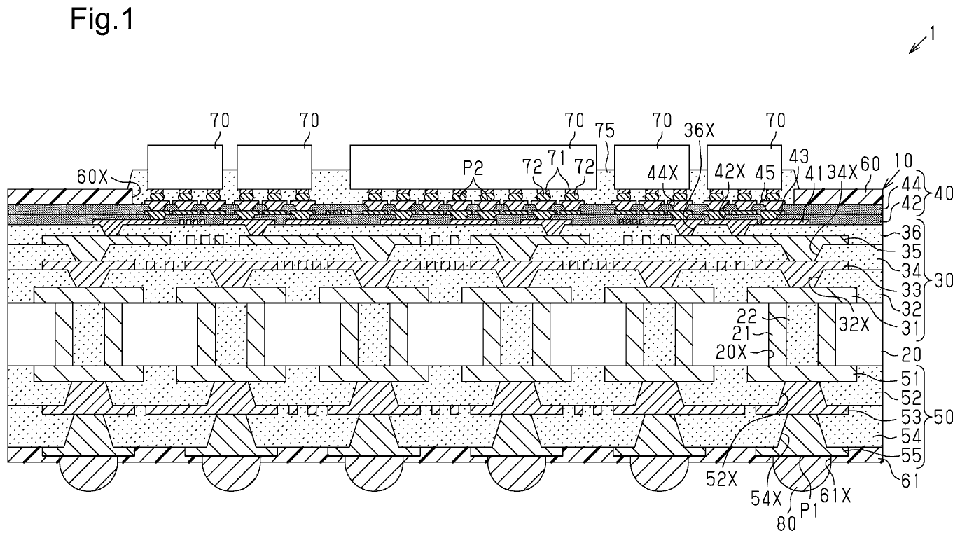

As illustrated in FIG. 1, a semiconductor device 1 includes a wiring substrate 10, one or more (in the present embodiment, five) semiconductor chips 70 mounted on the wiring substrate 10, an underfill resin 75, and external connection terminals 80.

### Overall Structure of Wiring Substrate 10

The wiring substrate 10 includes a core substrate 20, a first wiring structure 30, a second wiring structure 40, a third wiring structure 50, a solder resist layer 60, and a solder resist layer 61. The first wiring structure 30, the second wiring structure 40, and the solder resist layer 60 are arranged at one side of the core substrate 20. The third wiring structure 50 and the solder resist layer 61 are arranged at the other side of the core substrate 20.

In the present embodiment, to facilitate understanding, a side of the wiring substrate 10 in FIG. 1 at which the solder resist layer 60 is located will be referred to as the upper side or one side, and a side of the wiring substrate 10 at which the solder resist layer 61 is located will be referred to as the lower side or the other side. Further, a surface of each part located at the same side as the solder resist layer 60 will be referred to as one surface or the upper surface, and a surface of each part located at the same side as the solder resist layer 61 will be referred to as the other surface or the lower surface. Nonetheless, the semiconductor device 1 may be used in a flipped state or arranged at any angle. In this specification, “plan view” refers to a view of a subject taken in a normal direction of one surface of the solder resist layer 60, and “planar shape” refers to a shape of a subject taken in the normal direction of one surface of the solder resist layer 60.

The wiring substrate 10 may have any planar shape and any size. The wiring substrate 10 has, for example, a rectangular planar shape. The wiring substrate 10 may have a planar size of approximately 30 mm×30 mm to 80 mm×80 mm.

### Structure of Core Substrate 20

The core substrate 20 may be, for example, a glass epoxy substrate in which a glass cloth is impregnated with a thermosetting insulating resin, such as an epoxy-based resin or the like. The core substrate 20 may be, for example, a substrate in which a woven cloth or non-woven cloth of glass fibers, carbon fibers, aramid fibers, or the like is impregnated with a thermosetting insulating resin, such as an epoxy-based resin or the like. The core substrate 20 may have a thermal expansion coefficient (coefficient of thermal expansion, CTE) of, for example, approximately 4 ppm/° C. to 8 ppm/° C. The core substrate 20 may have a thickness of, for example, approximately 400 μm to 1600 μm. In the drawings, the glass cloth or the like is not illustrated.

The core substrate 20 includes through holes 20X extending through the core substrate 20 in a thickness-wise direction. The through holes 20X may have any planar shape and any size. The through holes 20X may each have, for example, a circular planar shape having a diameter of approximately 50 μm to 200 μm. The through holes 20X may have a pitch of, for example, approximately 100 μm to 400 μm.

The core substrate 20 includes a through-electrode 21 formed on a wall surface of each of the through holes 20X and extending through the core substrate 20 in the thickness-wise direction. An inner side of the through-electrode 21 in the through hole 20X in the example illustrated in FIG. 1, or a central part of the through hole 20X, is filled with a resin portion 22. The material of the through-electrodes 21 may be, for example, copper (Cu) or a copper alloy. The through-electrode 21 may have a thickness of, for example, approximately 15 μm to 35 μm. The material of the resin portion 22 may be, for example, an insulating resin, such as an epoxy-based resin or the like.

### First Wiring Structure 30

The first wiring structure 30 is located on an upper surface of the core substrate 20. The first wiring structure 30 is a wiring structure including one or more first wiring layers and one or more first insulating layers. The first wiring structure 30 of the present embodiment includes a structure in which a first wiring layer 31, a first insulating layer 32, a first wiring layer 33, a first insulating layer 34, a first wiring layer 35, and a first insulating layer 36 are sequentially stacked on the upper surface of the core substrate 20.

The material of the first wiring layers 31, 33, and 35 may be, for example, copper or a copper alloy. The first wiring layers 31, 33, and 35 may have a thermal expansion coefficient of, for example, approximately 15 ppm/° C. to 18 ppm/° C. The first wiring layers 31, 33, and 35 may each have a thickness of, for example, approximately 8 μm to 35 μm. The first wiring layers 31, 33, and 35 may each have a line/space (L/S) of, for example, approximately 10 μm/10 μm to 50 μm/50 μm. The “line” in “line/space” indicates the width of wiring, and the “space” indicates the distance between adjacent wiring parts (wiring interval). For example, when the line/space is 10 μm/10 μm to 50 μm/50 μm, the wiring width is 10 μm or greater and 50 μm or less, and the wiring interval is 10 μm or greater and 50 μm or less. The wiring width does not have to be equal to the wiring interval.

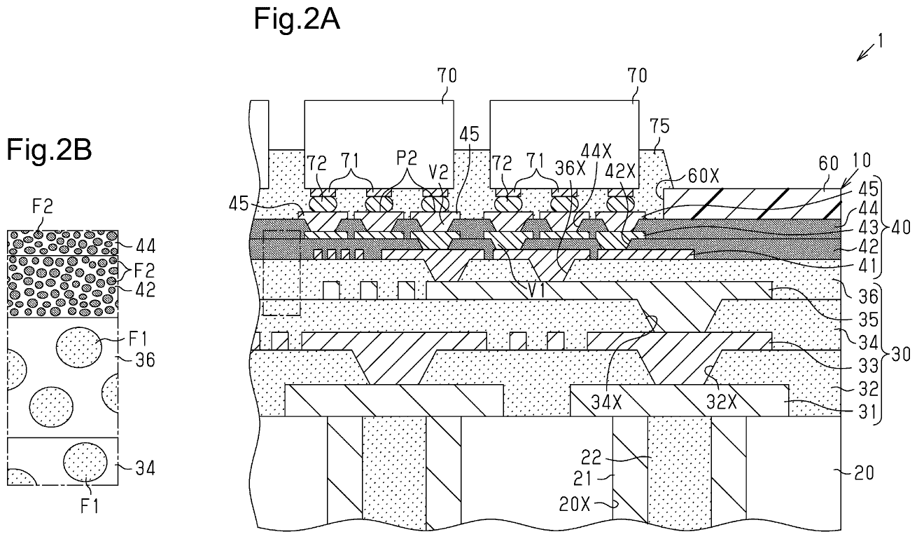

The first insulating layers 32, 34, and 36 include a non-photosensitive resin as a main component. The first insulating layers 32, 34, and 36 may include, for example, a thermosetting non-photosensitive resin, such as an epoxy-based resin, an imide-based resin, a phenol-based resin, a cyanate-based resin, or the like, as a main component. The first insulating layers 32, 34, and 36 contain, for example, a first filler F1 (refer to FIG. 2B), such as silica, alumina, or the like. The first insulating layers 32, 34, and 36 have a thermal expansion coefficient higher than the thermal expansion coefficient of the core substrate 20. The thermal expansion coefficient of the first insulating layers 32, 34, and 36 may be, for example, approximately 15 ppm/° C. to 25 ppm/° C. In the present specification, the thermal expansion coefficient of the first insulating layers 32, 34, and 36 may correspond to a combined value of the thermal expansion coefficient of each of the first insulating layers 32, 34, and 36, or may correspond to the thermal expansion coefficient of any one of the first insulating layers 32, 34, and 36. The first insulating layers 32, 34, and 36 may each have a thickness, for example, less than the thickness of the core substrate 20. The thickness of each of the first insulating layers 32, 34, and 36 may be, for example, approximately 30 μm to 70 μm. The first insulating layers 32, 34, and 36 may have the same thickness or different thicknesses.

The first wiring layer 31 is located on the upper surface of the core substrate 20. The first wiring layer 31 is electrically connected to the through-electrodes 21.

The first insulating layer 32 is located on the upper surface of the core substrate 20 and covers the first wiring layer 31. The first insulating layer 32 includes through holes 32X extending through the first insulating layer 32 in the thickness-wise direction and exposing parts of an upper surface of the first wiring layer 31 at given locations.

The first wiring layer 33 is located on an upper surface of the first insulating layer 32. The first wiring layer 33 is electrically connected to the first wiring layer 31 by via wirings formed in the through holes 32X. The first wiring layer 33 is, for example, formed integrally with the via wirings that fill the through holes 32X.

The first insulating layer 34 is located on the upper surface of the first insulating layer 32 and covers the first wiring layer 33. The first insulating layer 34 includes through holes 34X extending through the first insulating layer 34 in the thickness-wise direction and exposing parts of an upper surface of the first wiring layer 33 at given locations.

The first wiring layer 35 is located on an upper surface of the first insulating layer 34. The first wiring layer 35 is electrically connected to the first wiring layer 33 by via wirings formed in the through holes 34X. The first wiring layer 35 is, for example, formed integrally with the via wirings that fill the through holes 34X.

The first insulating layer 36 is located on the upper surface of the first insulating layer 34 and covers the first wiring layer 35. The first insulating layer 36 includes through holes 36X extending through the first insulating layer 36 in the thickness-wise direction and exposing parts of an upper surface of the first wiring layer 35 at given locations.

The through holes 32X, 34X, and 36X are each tapered such that its diameter (opening width) decreases from the upper side (facing second wiring structure 40) toward the lower side (facing core substrate 20) in FIG. 1. For example, the through holes 32X, 34X, and 36X each have the shape of an inverted truncated cone such that its upper open end has a larger diameter than its lower open end. The diameter of the upper open ends of the through holes 32X, 34X, and 36X may be, for example, approximately 60 μm to 70 μm.

### Third Wiring Structure 50

The third wiring structure 50 is located on a lower surface of the core substrate 20. The third wiring structure 50 is a wiring structure including one or more third wiring layers and one or more third insulating layers. The third wiring structure 50 of the present embodiment includes a structure in which a third wiring layer 51, a third insulating layer 52, a third wiring layer 53, a third insulating layer 54, and a third wiring layer 55 are sequentially stacked on the lower surface of the core substrate 20.

The material of the third wiring layers 51, 53, and 55 may be, for example, copper or a copper alloy. The third wiring layers 51, 53, and 55 may have a thermal expansion coefficient of, for example, approximately 15 ppm/° C. to 18 ppm/° C. The third wiring layers 51, 53, and 55 may each have a thickness of, for example, approximately 8 μm to 35 μm. The third wiring layers 51, 53, and 55 may each have a line/space (L/S) of, for example, approximately 10 μm/10 μm to 50 μm/50 μm.

The third insulating layers 52 and 54 include a non-photosensitive resin as a main component. The third insulating layers 52, and 54 may include, for example, a thermosetting non-photosensitive resin, such as an epoxy-based resin, an imide-based resin, a phenol-based resin, a cyanate-based resin, or the like, as a main component. The third insulating layers 52 and 54 contain, for example, the same filler as the first filler F1 illustrated in FIG. 2B. The third insulating layers 52 and 54 have a thermal expansion coefficient higher than the thermal expansion coefficient of the core substrate 20. The thermal expansion coefficient of the third insulating layers 52 and 54 is, for example, equivalent to the thermal expansion coefficient of the first insulating layers 32, 34, and 36. The thermal expansion coefficient of the third insulating layers 52 and 54 may be, for example, approximately 15 ppm/° C. to 25 ppm/° C. In the present specification, the thermal expansion coefficient of the third insulating layers 52 and 54 may correspond to a combined value of the thermal expansion coefficient of each of the third insulating layers 52 and 54, or may correspond to the thermal expansion coefficient of any one of the third insulating layers 52 and 54. For example, the thickness of each of the third insulating layers 52 and 54 is equal to the thickness of each of the first insulating layers 32, 34, and 36. Alternatively, the thickness of each of the third insulating layers 52 and 54 is greater than the thickness of each of the first insulating layers 32, 34, and 36. The thickness of each of the third insulating layers 52 and 54 is, for example, less than the thickness of the core substrate 20. The thickness of each of the third insulating layers 52 and 54 may be, for example, approximately 35 μm to 100 μm. The third insulating layers 52 and 54 may have the same thickness or different thicknesses.

The third wiring layer 51 is located on the lower surface of the core substrate 20. The third wiring layer 51 is electrically connected to the first wiring layer 31 by the through-electrodes 21.

The third insulating layer 52 is located on the lower surface of the core substrate 20 and covers the third wiring layer 51. The third insulating layer 52 includes through holes 52X extending through the third insulating layer 52 in the thickness-wise direction and exposing parts of a lower surface of the third wiring layer 51 at given locations.

The third wiring layer 53 is located on a lower surface of the third insulating layer 52. The third wiring layer 53 is electrically connected to the third wiring layer 51 by via wirings formed in the through holes 52X. The third wiring layer 53 is, for example, formed integrally with the via wirings that fill the through holes 52X.

The third insulating layer 54 is located on the lower surface of the third insulating layer 52 and covers the third wiring layer 53. The third insulating layer 54 includes through holes 54X extending through the third insulating layer 54 in the thickness-wise direction and exposing parts of a lower surface of the third wiring layer 53 at given locations.

The third wiring layer 55 is located on a lower surface of the third insulating layer 54. The third wiring layer 55 is electrically connected to the third wiring layer 53 by via wirings formed in the through holes 54X. The third wiring layer 55 is, for example, formed integrally with the via wirings that fill the through holes 54X.

The through holes 52X and 54X are each tapered such that its diameter (opening width) decreases from the lower side (facing solder resist layer 61) toward the upper side (facing core substrate 20) in FIG. 1. For example, the through holes 52X and 54X each have the shape of a truncated cone such that its lower open end has a larger diameter than its upper open end. The diameter of the lower open ends of the through holes 52X and 54X may be, for example, approximately 60 μm to 70 μm.

### Structure of Solder Resist Layer 61

The solder resist layer 61 is the outermost insulating layer (here, the lowermost insulating layer) of the wiring substrate 10. The solder resist layer 61 is located on a lower surface of the third wiring structure 50. In the example illustrated in FIG. 1, the solder resist layer 61 is located on the lower surface of the lower third insulating layer 54 of the third wiring structure 50, and covers the lowermost third wiring layer 55. The solder resist layer 61 is an insulating layer including a photosensitive resin as a main component. The material of the solder resist layer 61 may be, for example, a photosensitive insulating resin including a phenol-based resin, a polyimide-based resin, or the like, as a main component. The solder resist layer 61 may contain, for example, a filler, such as silica, alumina, or the like.

The solder resist layer 61 includes openings 61X that expose parts of a lower surface of the lowermost third wiring layer 55 as external connection pads P1. The external connection pads P1 are used for connection with the external connection terminals 80. The external connection terminals 80 are used to mount the wiring substrate 10 on a mounting substrate, such as a motherboard or the like.

A surface-processed layer may be formed, if necessary, on the third wiring layer 55 exposed from the openings 61X. Examples of the surface-processed layer include a Au layer, a Ni layer/Au layer (metal layer in which the Ni layer serves as bottom layer, and the Au layer is formed on the Ni layer), a Ni layer/Pd layer/Au layer (metal layer in which the Ni layer serves as bottom layer, and the Pd layer and the Au layer are sequentially formed on the Ni layer), or the like. The Au layer is a metal layer of Au or a Au alloy. The Ni layer is a metal layer of Ni or a Ni alloy. The Pd layer is a metal layer of Pd or a Pd alloy. The Au layer, the Ni layer, and the Pd layer may be, for example, metal layers formed by electroless plating, that is, electroless plating layers. Alternatively, the surface-processed layer may be an organic solderability preservative (OSP) film formed by performing an oxidation-resisting process, such as an OSP process, on the surface of the external connection pads P1. The OSP film may be, for example, an organic coating of an azole compound, an imidazole compound, or the like. The third wiring layer 55 exposed from the openings 61X (or surface-processed layer formed on the third wiring layer 55) may be used as external connection terminals.

The external connection pads P1 and the openings 61X may each have any planar shape and any size. The external connection pads P1 and the openings 61X may each have, for example, a circle planar shape having a diameter of approximately 200 μm to 300 μm.

### Second Wiring Structure 40

The second wiring structure 40 is located on an upper surface of the first wiring structure 30. The second wiring structure 40 includes a structure in which multiple second wiring layers and multiple second insulating layers are stacked. The second wiring structure 40 includes a structure in which a second wiring layer 41, a second insulating layer 42, a second wiring layer 43, a second insulating layer 44, and a second wiring layer 45 are sequentially stacked on an upper surface of the first insulating layer 36, which is the uppermost layer of the first wiring structure 30.

The second wiring structure 40 has a wiring density higher than the wiring density of the first wiring structure 30. The second wiring structure 40 is a high-density wiring layer (fine wiring layer) having a higher wiring density than the first wiring structure 30. The second wiring layers 41, 43, and 45 have a wiring width and a wiring interval smaller than the wiring width and the wiring interval of the first wiring layers 31, 33, and 35. The wiring density of the second wiring structure 40 is higher than the wiring density of the third wiring structure 50. The second wiring structure 40 is a high-density wiring layer having a higher wiring density than the third wiring structure 50. The second wiring layers 41, 43, and 45 have a wiring width and a wiring interval smaller than the wiring width and the wiring interval of the third wiring layers 51, 53, and 55. The second wiring layers 41, 43, and 45 may have a line/space (L/S) of, for example, approximately 3 μm/3 μm to 8 μm/8 μm. The term “L/S” indicates a wiring width (L) and a wiring interval(S).

The material of the second wiring layers 41, 43, and 45 may be, for example, copper or a copper alloy. The second wiring layers 41, 43, and 45 may have a thermal expansion coefficient of, for example, approximately 15 ppm/° C. to 18 ppm/° C. For example, the thickness of each of the second wiring layers 41, 43, and 45 is equivalent to the thickness of each of the first wiring layers 31, 33, and 35. Alternatively, the thickness of each of the second wiring layers 41, 43, and 45 is less than the thickness of each of the first wiring layers 31, 33, and 35. The second wiring layers 41, 43, and 45 may each have a thickness of, for example, approximately 8 μm to 15 μm.

The second insulating layers 42 and 44 include a non-photosensitive resin as a main component. The second insulating layers 42 and 44 may include, for example, a thermosetting non-photosensitive resin, such as an epoxy-based resin, an imide-based resin, a phenol-based resin, a cyanate-based resin, or the like, as a main component. The second insulating layers 42 and 44 have a thermal expansion coefficient higher than the thermal expansion coefficient of the core substrate 20 and lower than the thermal expansion coefficient of the first insulating layers 32, 34, and 36. The thermal expansion coefficient of the second insulating layers 42 and 44 is lower than the thermal expansion coefficient of the third insulating layers 52 and 54. The thermal expansion coefficient of the second insulating layers 42 and 44 may be, for example, approximately 8 ppm/° C. to 18 ppm/° C. In the present specification, the thermal expansion coefficient of the second insulating layers 42 and 44 may correspond to a combined value of the thermal expansion coefficient of each of the second insulating layers 42 and 44, or may correspond to the thermal expansion coefficient of any one of the second insulating layers 42 and 44.

As illustrated in FIG. 2B, the second insulating layers 42 and 44 contain, for example, a second filler F2, such as silica, alumina, or the like. The average particle diameter of the second filler F2 is, for example, smaller than the average particle diameter of the first filler F1 contained in the first insulating layers 32, 34, and 36. The maximum particle diameter of the second filler F2 is smaller than the maximum particle diameter of the first filler F1. The average particle diameter of the first filler F1 may be, for example, 0.5 μm or less. The maximum particle diameter of the first filler F1 may be, for example, 5 μm or less.

The average particle diameter of the second filler F2 may be, for example, 0.1 μm or less. The maximum particle diameter of the second filler F2 may be, for example, 1 μm or less. The average particle diameters and the maximum particle diameters of the first filler F1 and the second filler F2 may be measured, for example, using a scanning electron microscope.

In the second insulating layers 42 and 44, the thermal expansion coefficient of the second insulating layer 42 and 44 may be adjusted by, for example, adjusting the content rate of the second filler F2. The content rate of the second filler F2 is, for example, higher than the content rate of the first filler F1. The content rate of the first filler F1 may be, for example, approximately 60 wt % to 70 wt %. The content rate of the second filler F2 may be, for example, approximately 75 wt % to 85 wt %.

In the present embodiment, the content rate of the second filler F2 is adjusted to be higher than the content rate of the first filler F1 so that the thermal expansion coefficient of the second insulating layers 42 and 44 is lower than the thermal expansion coefficient of the first insulating layers 32, 34, and 36. In an insulating layer including a photosensitive resin as a main component, if the content of the filler is excessively large, it may become impossible to perform exposure. Therefore, the amount of filler that may be contained has a limit (upper limit). Accordingly, an insulating layer including a photosensitive resin as a main component is likely to have a higher thermal expansion coefficient than an insulating layer including a non-photosensitive resin as a main component. In this respect, when adjusting the thermal expansion coefficient of the second insulating layers 42 and 44 by adjusting the content rate of the second filler F2, it is preferred that the second insulating layers 42 and 44 include a non-photosensitive resin as a main component.

As illustrated in FIG. 2A, the thickness of each of the second insulating layers 42 and 44 is, for example, less than the thickness of the core substrate 20. The thickness of each of the second insulating layers 42 and 44 is, for example, less than the thickness of each of the first insulating layers 32, 34, and 36. The thickness of each of the second insulating layers 42 and 44 is, for example, less than the thickness of each of the third insulating layers 52 and 54. The thickness of each of the second insulating layers 42 and 44 may be, for example, approximately 1 μm to 10 μm. The second insulating layers 42 and 44 may have the same thickness or different thicknesses.

The second wiring layer 41 is located on the upper surface of the uppermost first insulating layer 36 of the first wiring structure 30. The second wiring layer 41 is electrically connected to the first wiring layer 35 by via wirings formed in the through holes 36X. The second wiring layer 41 is, for example, formed integrally with the via wirings that fill the through holes 36X.

The second insulating layer 42 is located on the upper surface of the uppermost first insulating layer 36 of the first wiring structure 30 and covers the second wiring layer 41. The second insulating layer 42 includes through holes 42X extending through the second insulating layer 42 in the thickness-wise direction and exposing parts of an upper surface of the second wiring layer 41 at given locations.

The second wiring layer 43 is located on an upper surface of the second insulating layer 42. The second wiring layer 43 is electrically connected to the second wiring layer 41 by via wirings V1 formed in the through holes 42X. The second wiring layer 43 is, for example, formed integrally with the via wirings V1 that fill the through holes 42X.

The second insulating layer 44 is located on the upper surface of the second insulating layer 42 and covers the second wiring layer 43. The second insulating layer 44 includes through holes 44X extending through the second insulating layer 44 in the thickness-wise direction and exposing parts of an upper surface of the second wiring layer 43 at given locations.

The through holes 42X and 44X are each tapered such that its diameter (opening width) decreases from the upper side (facing solder resist layer 60) toward the lower side (facing first wiring structure 30) in FIG. 2A. For example, the through holes 42X and 44X each have the shape of an inverted truncated cone such that its upper open end has a larger diameter than its lower open end. The opening diameter of each of the through holes 42X and 44X is, for example, smaller than the opening diameter of each of the through holes 32X, 34X, and 36X. The diameter of the upper open ends of the through holes 42X and 44X may be, for example, approximately 5 μm to 10 μm.

The second wiring layer 45 is located on an upper surface of the second insulating layer 44. The second wiring layer 45 is electrically connected to the second wiring layer 43 by via wirings V2 formed in the through holes 44X. The second wiring layer 45 is, for example, formed integrally with the via wirings V2 that fill the through holes 44X. The second wiring layer 45 includes, for example, pads P2. The pad P2 may have any planar shape and any size. The pads P2 may have, for example, a circular planar shape having a diameter of approximately 20 μm to 30 μm. The pads P2 may have a pitch of, for example, approximately 40 μm to 60 μm. The pads P2 act as electronic component mounting pads for electrical connection with an electronic component, such as the semiconductor chip 70 or the like.

A surface-processed layer may be formed, if necessary, on surface (both upper and side surfaces or only upper surface) of the pads P2. The surface-processed layer may be an OSP film or a metal layer, such as a Au layer, a Ni layer/Au layer, a Ni layer/Pd layer/Au layer, or the like.

### Structure of Solder Resist Layer 60

The solder resist layer 60 is the outermost insulating layer (here, the uppermost insulating layer) of the wiring substrate 10. The solder resist layer 60 is located on an upper surface of the second wiring structure 40. The solder resist layer 60 is located on the upper surface of the second insulating layer 44, which is the uppermost layer of the second wiring structure 40. The solder resist layer 60 is an insulating layer including a photosensitive resin as a main component. The material of the solder resist layer 60 may be, for example, a photosensitive insulating resin including a phenol-based resin, a polyimide-based resin, or the like, as a main component. The solder resist layer 60 may contain, for example, a filler, such as silica, alumina, or the like.

The solder resist layer 60 is located on the upper surface of the second insulating layer 44 and exposes the pads P2. For example, in plan view, the solder resist layer 60 surrounds a mounting region in which the semiconductor chips 70 are mounted. In other words, the solder resist layer 60 includes an open portion 60X that exposes the upper surface of the second wiring structure 40 located in the mounting region. The open portion 60X overlaps the mounting region in plan view. The open portion 60X extends through the solder resist layer 60 in the thickness-wise direction. The open portion 60X exposes the upper surface of the second insulating layer 44 and the pads P2 located in the mounting region.

### Structure of Semiconductor Chip 70

The semiconductor chips 70 each include connection terminals 71 formed on a circuit formation surface (here, lower surface) of the semiconductor chip 70. The semiconductor chip 70 is, for example, a silicon (Si) component. The semiconductor chip 70 includes, for example, a thin semiconductor substrate of silicon or the like, a passivation film that is formed on the semiconductor substrate and covers the circuit formation circuit where semiconductor integrated circuits (not illustrated) are formed, and the connection terminals 71 that are formed on the circuit formation surface.

The semiconductor chip 70 is mounted on the wiring substrate 10. The semiconductor chip 70 is, for example, flip-chip mounted on the wiring substrate 10. For example, the connection terminals 71 of the semiconductor chip 70 are electrically connected to the pads P2 of the wiring substrate 10 by a solder layer 72. Therefore, the semiconductor chip 70 is electrically connected to the pads P2 by the connection terminals 71 and the solder layer 72. The semiconductor chips 70 are, for example, electrically connected to one another via the second wiring layer 45, which includes the pads P2.

The semiconductor chips 70 may each be, for example, a logic chip, such as a central processing unit (CPU) chip, a graphics processing unit (GPU) chip, or the like. Furthermore, the semiconductor chips 70 may each be, for example, a memory chip, such as a dynamic random access memory (DRAM) chip, a flash memory chip, or the like. The semiconductor chips 70 include, for example, a logic chip and a memory chip.

The semiconductor chips 70 may each have any planar shape and any size. The semiconductor chip 70 has, for example, a rectangular planar shape. The semiconductor chip 70 may have a planar size of, for example, approximately 3 mm×3 mm to 12 mm×12 mm. The semiconductor chip 70 may have a thickness of, for example, approximately 50 μm to 300 μm. The semiconductor chip 70 may have a thermal expansion coefficient, for example, lower than the thermal expansion coefficient of the second insulating layers 42 and 44. The thermal expansion coefficient of the semiconductor chip 70 is, for example, lower than the thermal expansion coefficient of the first insulating layers 32, 34, and 36. The thermal expansion coefficient of the semiconductor chip 70 is, for example, lower than the thermal expansion coefficient of the core substrate 20. The thermal expansion coefficient of the semiconductor chip 70 may be, for example, approximately 2 ppm/° C. to 5 ppm/° C.

The connection terminals 71 may be, for example, metal posts. The connection terminals 71 are rod-shaped connection terminals extending downward from the circuit formation surface of the semiconductor chip 70. The connection terminals 71 of the present example are, for example, cylindrical. The connection terminal 71 may have a thickness of, for example, approximately 10 μm to 20 μm. The connection terminal 71 may have a diameter of, for example, approximately 20 μm to 30 μm. The connection terminals 71 may have a pitch of, for example, approximately 40 μm to 60 μm. The material of the connection terminals 71 may be, for example, copper or a copper alloy. In addition to metal posts, the connection terminals 71 may be metal bumps, such as gold bumps, or the like.

The solder layer 72 is joined to the pads P2 and the connection terminals 71. The material of the solder layer 72 may be, for example, a lead (Pb) free solder of tin (Sn)-silver (Ag), Sn—Cu, or Sn—Ag—Cu. The solder layer 72 may have a thickness of, for example, approximately 5 μm to 15 μm.

### Structure of Underfill Resin 75

As illustrated in FIG. 1, the underfill resin 75 fills the gap between the wiring substrate 10 and the semiconductor chips 70. The underfill resin 75 fills the gap between the upper surface of the second insulating layer 44 exposed from the open portion 60X and the lower surface of the semiconductor chips 70. The material of the underfill resin 75 may be, for example, an insulating resin, such as an epoxy-based resin, or the like.

### Structure of External Connection Terminal 80

The external connection terminals 80 are formed on the external connection pads P1 of the wiring substrate 10. The external connection terminals 80 are, for example, connection terminals for electrical connection with pads arranged on a mounting substrate, such as a motherboard (not illustrated) or the like. The external connection terminals 80 may be, for example, solder balls or lead pins. In the present embodiment, the external connection terminals 80 are solder balls.

As described above, in the semiconductor device 1, the thermal expansion coefficient increases in the order of the semiconductor chips 70, the core substrate 20, the second insulating layers 42 and 44, the first insulating layers 32, 34, and 36, and the third insulating layers 52 and 54. Such setting of the thermal expansion coefficient effectively restricts warping of the wiring substrate 10 and the semiconductor device 1. This advantage will be discussed later.

### Method for Manufacturing Wiring Substrate 10

A method for manufacturing the wiring substrate 10 will now be described. To facilitate understanding, portions that will become final elements of the wiring substrate 10 are given the same reference characters as the final elements.

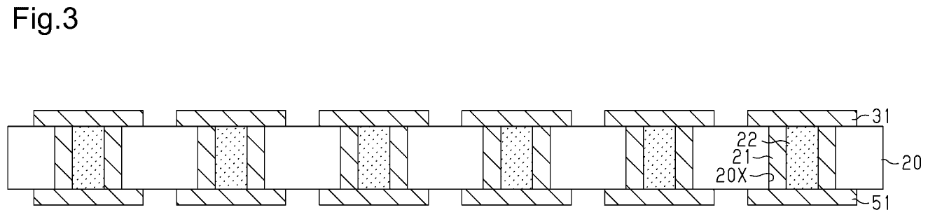

First, in the step illustrated in FIG. 3, a structural body is formed including the core substrate 20, the through-electrodes 21, the resin portions 22, the first wiring layer 31 formed on the upper surface of the core substrate 20, and the third wiring layer 51 formed on the lower surface of the core substrate 20. This structural body may be manufactured by a manufacturing process known in the art. Thus, the process will not be described in detail.

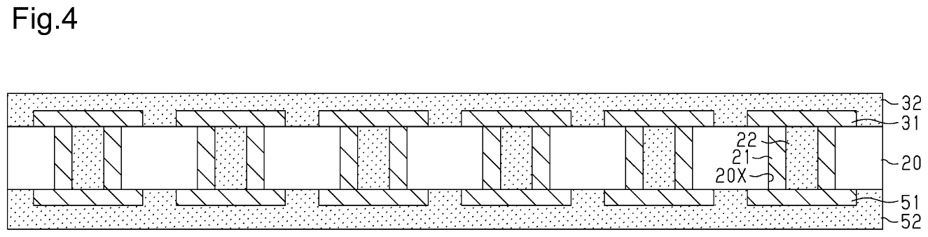

In the subsequent step illustrated in FIG. 4, the first insulating layer 32 is formed to cover the first wiring layer 31 and the upper surface of the core substrate 20. Further, the third insulating layer 52 is formed to cover the third wiring layer 51 and the lower surface of the core substrate 20. For example, when resin films are used as the first insulating layer 32 and the third insulating layer 52, the upper surface and the lower surface of the core substrate 20 are laminated with the resin films. Then, the resin films are heated at a curing temperature or higher (e.g., approximately 130° C. to 200° C.) while being pressed so that the resin films are cured to form the first insulating layer 32 and the third insulating layer 52. The resin film may be, for example, a film of a thermosetting resin including an epoxy-based resin as a main component. Alternatively, when a liquid or a paste of insulating resin is used as the first insulating layer 32 and the third insulating layer 52, the liquid or paste of insulating resin is applied to the upper surface and the lower surface of the core substrate 20 by spin coating or the like. Then, the applied insulating resin is heated at a curing temperature or higher so that the insulating resin is cured to form the first insulating layer 32 and the third insulating layer 52. The liquid or paste of insulating resin may be, for example, a thermosetting resin including an epoxy-based resin as a main component.

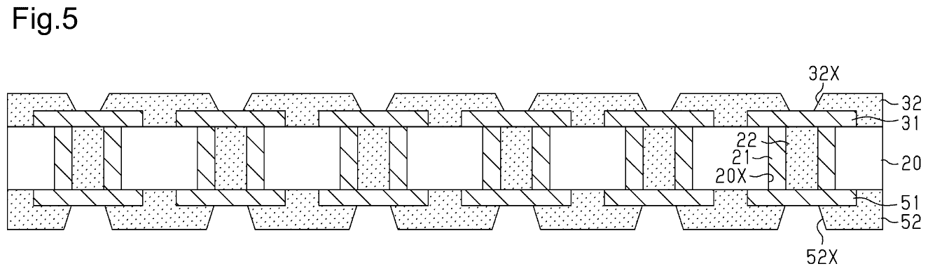

In the subsequent step illustrated in FIG. 5, the through holes 32X are formed at given locations of the first insulating layer 32 to expose parts of the upper surface of the first wiring layer 31. Also, the through holes 52X are formed at given locations of the third insulating layer 52 to expose parts of the lower surface of the third wiring layer 51. The through holes 32X and 52X may be formed by, for example, laser drilling that uses a CO₂ laser, a UV-YAG laser, or the like.

When the through holes 32X and 52X are formed by laser drilling, a desmear process is then performed to remove resin smears from the surfaces of the first wiring layer 31 and the third wiring layer 51 exposed at the bottom of the through holes 32X and 52X. The desmear process performed in this step may be, for example, a wet desmear process that uses a potassium permanganate solution or the like.

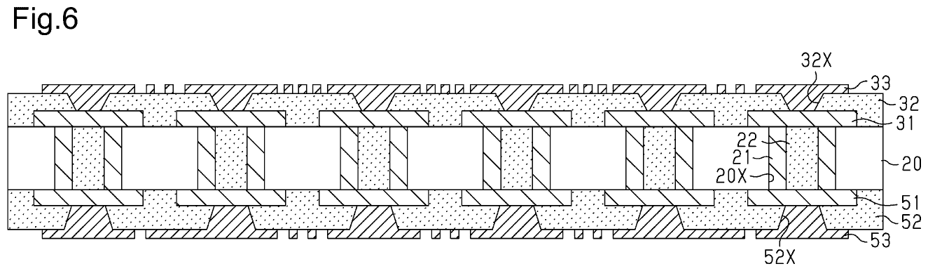

In the subsequent step illustrated in FIG. 6, the via wirings are formed to fill the through holes 32X of the first insulating layer 32, and the first wiring layer 33 is formed on the upper surface of the first insulating layer 32. The first wiring layer 33 is electrically connected to the first wiring layer 31 by the via wirings arranged in the through holes 32X. Also, the via wirings are formed to fill the through holes 52X of the third insulating layer 52, and the third wiring layer 53 is formed on the lower surface of the third insulating layer 52. The third wiring layer 53 is electrically connected to the third wiring layer 51 by the via wirings arranged in the through holes 52X. The first wiring layer 33 and the third wiring layer 53 may be formed by any type of various wiring formation processes, such as a semi-additive process, a subtractive process, or the like.

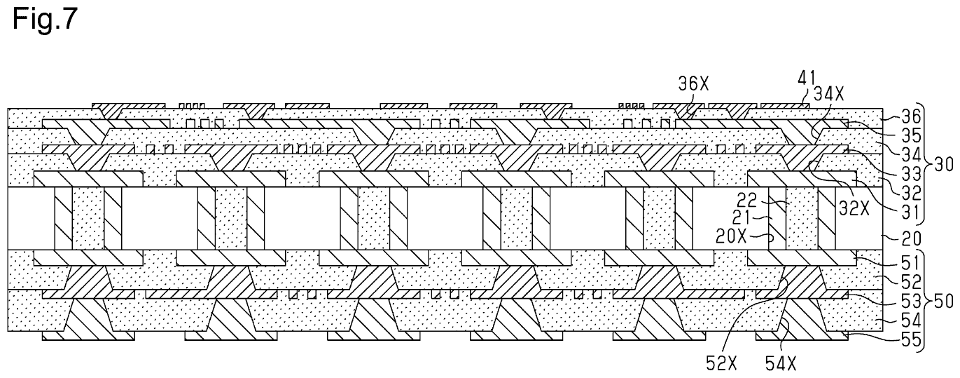

In the subsequent step illustrated in FIG. 7, the same steps as those illustrated in FIGS. 4 to 6 are performed to stack the first insulating layer 34 and the first wiring layer 35 on the upper surface of the first insulating layer 32, and stack the third insulating layer 54 and the third wiring layer 55 on the lower surface of the third insulating layer 52. The same steps as those illustrated in FIGS. 4 to 6 are further performed to stack the first insulating layer 36 and the second wiring layer 41 on the upper surface of the first insulating layer 34. The present step forms the first wiring structure 30 on the upper surface of the core substrate 20, and forms the third wiring structure 50 on the lower surface of the core substrate 20. The line/space of the second wiring layer 41 is smaller than the line/space of the first wiring layers 31, 33, and 35.

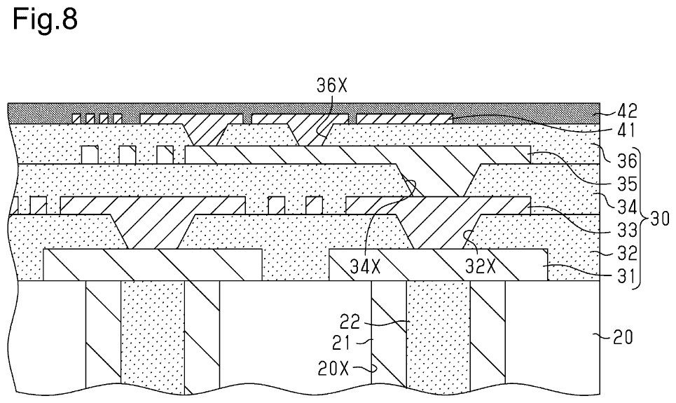

In the subsequent step illustrated in FIG. 8, the second insulating layer 42 is formed to cover the second wiring layer 41 and the upper surface of the first insulating layer 36. For example, when a resin film is used as the second insulating layer 42, the upper surface of the first insulating layer 36 is laminated with the resin film. Then, the resin film is heated at a curing temperature or higher (e.g., approximately 130° C. to 200° C.) while being pressed so that the resin film is cured to form the second insulating layer 42. Alternatively, when a liquid or a paste of insulating resin is used as the second insulating layer 42, the liquid or paste of insulating resin is applied to the upper surface of the first insulating layer 36 by spin coating or the like. Then, the applied insulating resin is heated at a curing temperature or higher so that the insulating resin is cured to form the second insulating layer 42. The insulating resin serving as the second insulating layer 42 may be, for example, a thermosetting resin, such as an epoxy-based resin, a polyimide-based resin, or the like.

Preferably, the second insulating layer 42 includes, for example, a thermosetting non-photosensitive resin, such as an epoxy-based resin, a polyimide-based resin, or the like, as a main component. The second insulating layer 42 contains the second filler F2 (refer to FIG. 2B), such as silica, alumina, or the like. The average particle diameter and the maximum particle diameter of the second filler F2 contained in the second insulating layer 42 are smaller than the average particle diameter and the maximum particle diameter of the first filler F1 contained in the first insulating layers 32, 34, and 36 (refer to FIG. 2B). The content rate of the second filler F2 is higher than the content rate of the first filler F1. The thermal expansion coefficient of the second insulating layer 42 is set to be higher than the thermal expansion coefficient of the core substrate 20 and lower than the thermal expansion coefficient of the first insulating layers 32, 34, and 36. Furthermore, the second insulating layer 42 is formed to be thinner than each of the first insulating layers 32, 34, and 36.

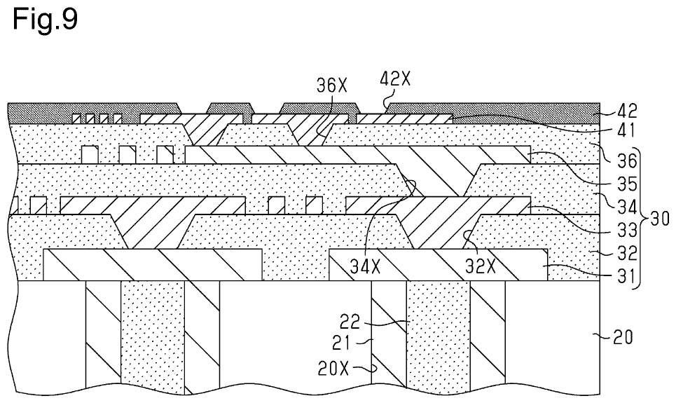

In the subsequent step illustrated in FIG. 9, the through holes 42X are formed at given locations of the second insulating layer 42 to expose parts of the upper surface of the second wiring layer 41. The through holes 42X may be formed, for example, by laser drilling. The opening diameter of the through holes 42X is smaller than the opening diameter of the through holes 32X, 34X, and 36X of the first wiring structure 30. Therefore, it is preferred that the through holes 42X are formed using an excimer laser, which is suitable for microfabrication.

When the through holes 42X are formed by laser drilling, a desmear process is then performed to remove resin smears from the surface of the second wiring layer 41 exposed at the bottom of the through hole 42X. The desmear process performed in this step may be, for example, a dry desmear process that uses a carbon tetrafluoride (CF₄) gas or the like.

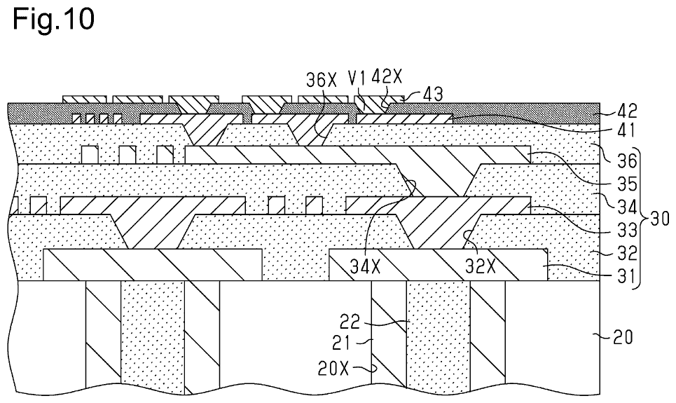

In the subsequent step illustrated in FIG. 10, the via wirings V1 are formed to fill the through holes 42X in the second insulating layer 42, and the second wiring layer 43 is formed on the upper surface of the second insulating layer 42. The second wiring layer 43 is electrically connected to the second wiring layer 41 by the via wirings V1 arranged in the through holes 42X. The line/space of the second wiring layer 43 is smaller than the line/space of the first wiring layers 31, 33, and 35. The second wiring layer 43 and the via wirings V1 may be formed by any type of various wiring formation processes, such as a semi-additive process, a subtractive process, or the like.

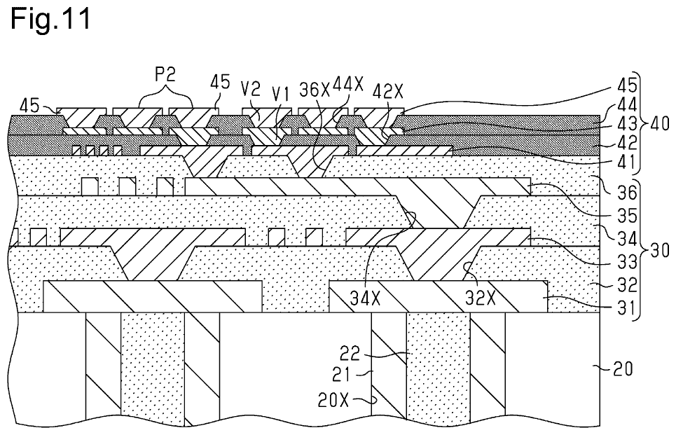

In the subsequent step illustrated in FIG. 11, the same steps as those illustrated in FIGS. 8 to 10 are performed to stack the second insulating layer 44 and the second wiring layer 45 on the upper surface of the second insulating layer 42. In this case, the second wiring layer 45 includes the pads P2. The present step forms the second wiring structure 40 on the upper surface of the first wiring structure 30.

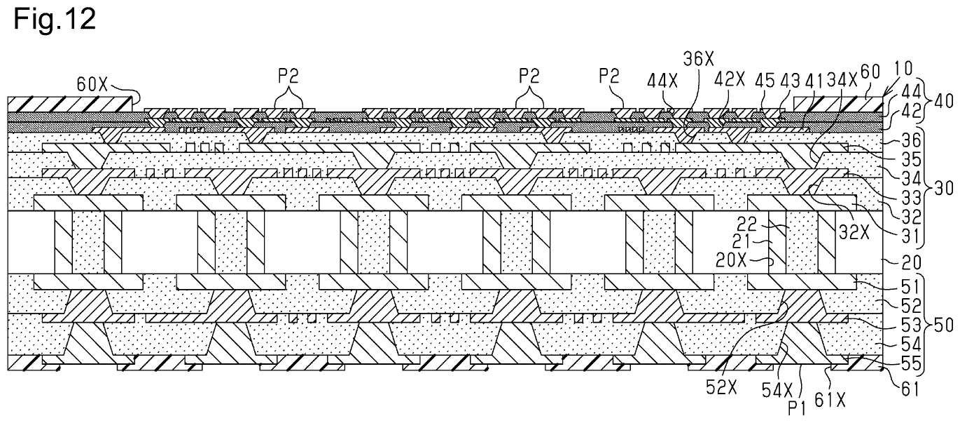

In the subsequent step illustrated in FIG. 12, the solder resist layer 60 is formed on the upper surface of the second insulating layer 44. The solder resist layer 60 includes the open portion 60X that exposes the pads P2. Also, the solder resist layer 61 is formed on the lower surface of the third insulating layer 54. The solder resist layer 61 includes the openings 61X that expose parts of the lower surface of the third wiring layer 55 as the external connection pads P1. The solder resist layers 60 and 61 may each be formed, for example, by applying a photosensitive solder resist film or a liquid solder resist layer and patterning the resist into a desired shape.

A surface-processed layer may be formed, if necessary, on the external connection pads P1 and the pads P2. The solder resist layer 61 may be formed at any time after the lowermost third wiring layer 55 is formed. For example, the solder resist layer 61 may be formed following the step illustrated in FIG. 7. The wiring substrate 10 of the present embodiment is manufactured through the manufacturing steps described above.

### Method for Manufacturing Semiconductor Device 1

A method for manufacturing the semiconductor device 1 will now be described.

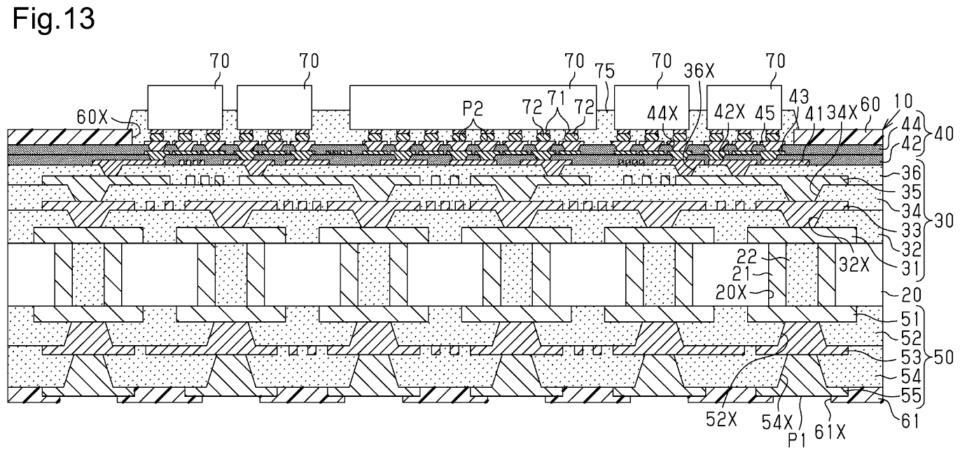

First, in the step illustrated in FIG. 13, the semiconductor chips 70 are prepared. The semiconductor chips 70 each include the connection terminals 71 and the solder layer 72 formed on the lower surface of the connection terminals 71. The semiconductor chips 70 may be manufactured by a manufacturing process known in the art. Thus, the process will not be described in detail.

Next, the connection terminals 71 of the semiconductor chips 70 are joined to the pad P2 of the wiring substrate 10. For example, the wiring substrate 10 is aligned with the semiconductor chips 70, and then reflow soldering is performed to melt the solder layer 72 and electrically connect the connection terminals 71 and the pads P2. The temperature of the reflow soldering is, for example, approximately 260° C.

Subsequently, the underfill resin 75 is added to fill the gap between the semiconductor chips 70 and the wiring substrate 10, and the added underfill resin 75 is cured. Further, the external connection terminals 80 (refer to FIG. 1) are formed on the external connection pads P1. The external connection terminals 80 may be formed at any time after the external connection pads P1 are formed. For example, the external connection terminals 80 may be formed before the semiconductor chips 70 are mounted on the wiring substrate 10. The semiconductor device 1 of the present embodiment is manufactured through the manufacturing steps described above.

### Operations of Wiring Substrate 10 and Semiconductor Device 1

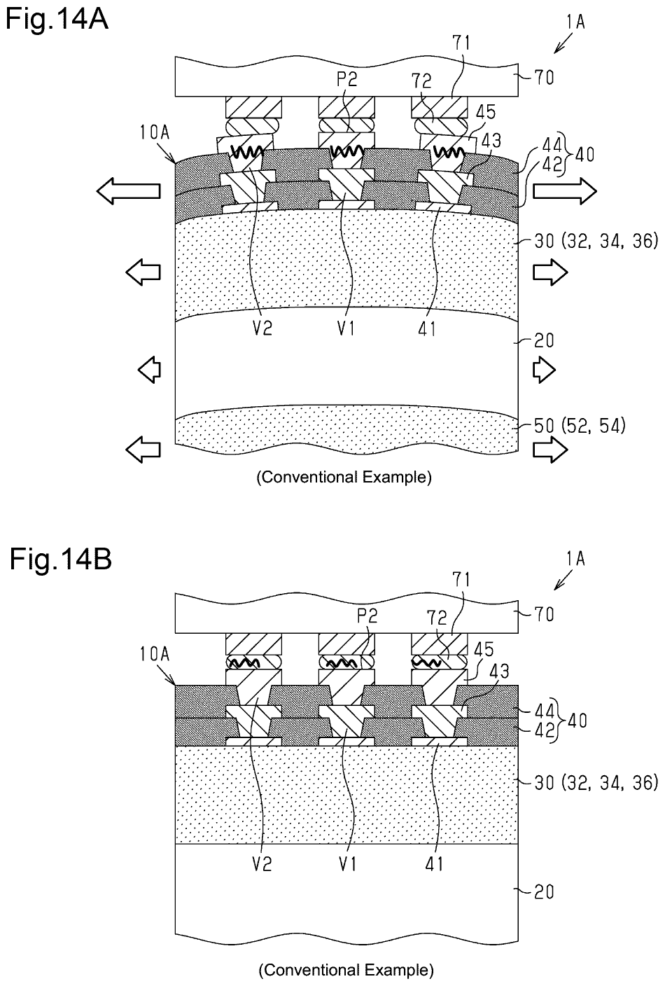

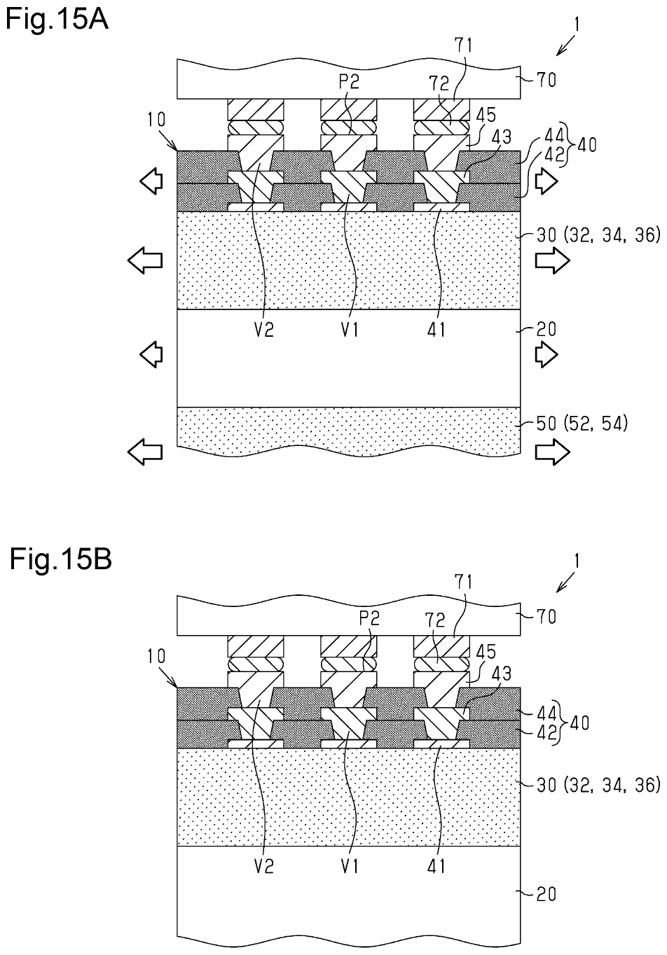

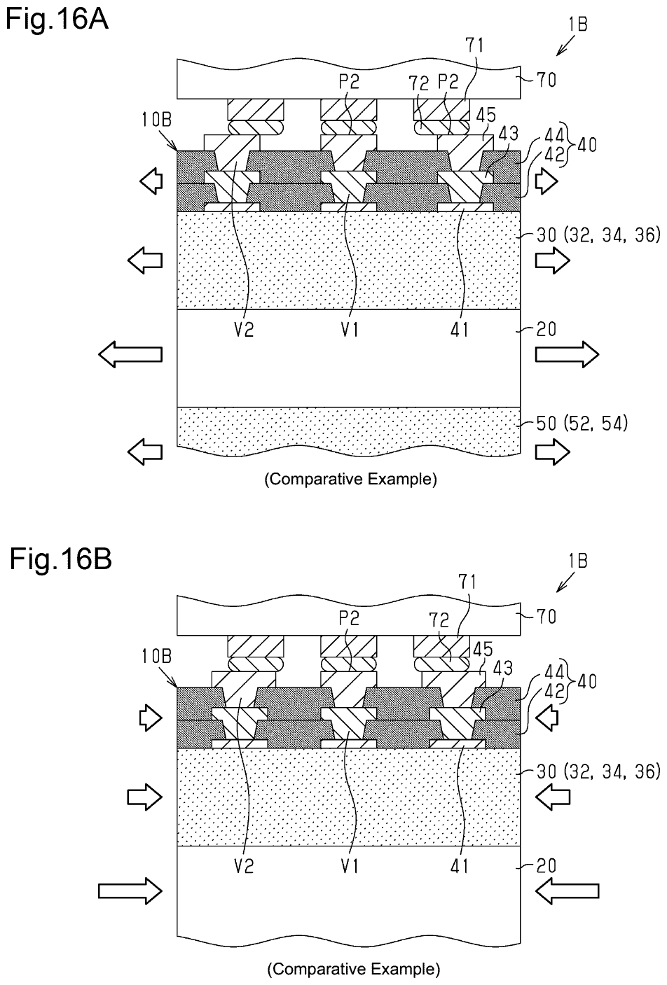

The operations of the wiring substrate 10 and the semiconductor device 1 will now be described with reference to FIGS. 14A to 16B. FIGS. 14A and 14B are schematic cross-sectional views of an example of a conventional semiconductor device 1A. FIGS. 15A and 15B are schematic cross-sectional views enlarging part of the semiconductor device 1 illustrated in FIG. 1. FIGS. 16A and 16B are schematic cross-sectional views of a comparative semiconductor device 1B. In FIGS. 14A to 16B, the first wiring structure 30 is illustrated as a single layer to simplify illustration. Further, in FIGS. 14A, 15A, and 16A, the third wiring structure 50 is illustrated as a single layer to simplify illustration. The arrows in FIGS. 14A to 16B schematically represent amounts of expansion or contraction of the components. In FIGS. 14A to 16B, a longer arrow indicates a greater amount of expansion or contraction of the component.

The semiconductor devices 1, 1A, and 1B have the same layer structure. The semiconductor devices 1, 1A, and 1B differ from one another in relationship between the thermal expansion coefficients of the components.

The conventional semiconductor device 1A will now be described with reference to FIGS. 14A and 14B.

As illustrated in FIGS. 14A and 14B, the semiconductor device 1A includes a wiring substrate 10A. In the wiring substrate 10A of the conventional example, the thermal expansion coefficient increases in the order of the core substrate 20, the first insulating layers 32, 34, and 36, the third insulating layers 52 and 54, and the second insulating layers 42 and 44. For example, in the wiring substrate 10A, the thermal expansion coefficient of the third insulating layers 52 and 54 is set to 20 ppm/° C., the thermal expansion coefficient of the core substrate 20 is set to 7 ppm/° C., the thermal expansion coefficient of the first insulating layers 32, 34, and 36 is set to 20 ppm/° C., and the thermal expansion coefficient of the second insulating layers 42 and 44 is set to 37 ppm/° C. Accordingly, in the wiring substrate 10A of the conventional example, the thermal expansion coefficient significantly differs between above and below the core substrate 20.

When such a wiring substrate 10A of the conventional example is exposed to a high-temperature environment of approximately 260° C. when mounting the semiconductor chip 70, the difference (mismatch) of the thermal expansion coefficients between above and below the core substrates 20 may cause warping of the wiring substrate 10A. In the wiring substrate 10A illustrated in FIG. 14A, the core substrate 20 is less likely to expand compared to the first insulating layers 32, 34, and 36, the second insulating layers 42 and 44, and the third insulating layers 52 and 54. In this case, in the wiring substrate 10A, the thermal expansion coefficient of the second insulating layers 42 and 44, which are located above the core substrate 20, is higher than the thermal expansion coefficient of the third insulating layers 52 and 54, which are located below the core substrate 20. Accordingly, the second insulating layers 42 and 44, which are located above the core substrate 20, are more likely to expand compared to the third insulating layers 52 and 54, which are located below the core substrate 20. Therefore, as illustrated in FIG. 14A, when the wiring substrate 10A of the conventional example is exposed to a high-temperature environment, the second wiring structure 40 may warp into a convex shape, in other words, the upper surface of the uppermost second insulating layer 44 may warp into a convex shape. Such warpage may distort the second insulating layers 42 and 44. This distortion may result in cracking or breaking of the via wirings V1 and V2 in the second wiring structure 40.

In this manner, in the conventional semiconductor device 1A, the semiconductor chip 70 is mounted on the wiring substrate 10A that includes the distorted second insulating layers 42 and 44. Subsequently, when the temperature returns to room temperature, as illustrated in FIG. 14B, the wiring substrate 10A acts to return to its original state before the distortion. The force acting to return the wiring substrate 10A to the original state becomes internal stress that may cause, for example, cracks or breakage in the solder layer 72. This may lower the connection reliability between the semiconductor chip 70 and the wiring substrate 10A.

In contrast, in the wiring substrate 10 illustrated in FIG. 15A, the thermal expansion coefficient increases in the order of the core substrate 20, the second insulating layers 42 and 44, the first insulating layers 32, 34, and 36, and the third insulating layers 52 and 54. For example, in the wiring substrate 10, the thermal expansion coefficient of the third insulating layers 52 and 54 is set to 20 ppm/° C., the thermal expansion coefficient of the core substrate 20 is set to 7 ppm/° C., the thermal expansion coefficient of the first insulating layers 32, 34, and 36 is set to 20 ppm/° C., and the thermal expansion coefficient of the second insulating layers 42 and 44 are set to 10 ppm/° C.

In this manner, in the wiring substrate 10 of the present embodiment, the thermal expansion coefficient of the second insulating layers 42 and 44 is set to be lower than the thermal expansion coefficient of the first insulating layers 32, 34, and 36 and higher than the thermal expansion coefficient of the core substrate 20. Accordingly, the thermal expansion coefficient of the second insulating layers 42 and 44 is relatively close to the thermal expansion coefficient of the core substrate 20. Thus, even when the wiring substrate 10 is exposed to a high-temperature environment of approximately 260° C. when mounting the semiconductor chip 70, warping of the wiring substrate 10 is restricted effectively. In other words, when the wiring substrate 10 of the present embodiment is exposed to a high-temperature environment, the amount of warpage is less than that of the conventional wiring substrate 10A. This may also be confirmed through warpage simulations, which will be discussed later.

The wiring substrate 10 limits warping when the wiring substrate 10 is exposed to a high-temperature environment, thereby restricting distortion of the second insulating layers 42 and 44. This reduces the stress applied to the via wirings V1, V2, and the like in the second wiring structure 40. As a result, cracks or breakage are effectively avoided in the via wirings V1 and V2.

Subsequently, when the temperature returns to room temperature, as illustrated in FIG. 15B, the wiring substrate 10 acts to return to its original state before the distortion. In the wiring substrate 10 of the present embodiment, since the distortion under a high-temperature environment is restricted, changes in dimension are also relatively small when the temperature returns to room temperature. This reduces the internal stress produced in the wiring substrate 10 when returning to the original state. Thus, when the temperature returns to room temperature, cracks or breakage are effectively avoided in the solder layer 72 and the like. As a result, the semiconductor device 1 of the present embodiment appropriately maintains the connection reliability between the semiconductor chip 70 and the wiring substrate 10.

Next, the comparative semiconductor device 1B will now be described with reference to FIGS. 16A and 16B.

As illustrated in FIGS. 16A and 16B, the comparative semiconductor device 1B includes a wiring substrate 10B. In the wiring substrate 10B of the comparative example, the thermal expansion coefficient increases in the order of the second insulating layers 42 and 44, the first insulating layers 32 and 34, and 36, the third insulating layers 52 and 54, and the core substrate 20. For example, in the wiring substrate 10B, the thermal expansion coefficient of the third insulating layers 52 and 54 is set to 20 ppm/° C., the thermal expansion coefficient of the core substrate 20 is set to 25 ppm/° C., the thermal expansion coefficient of the first insulating layers 32, 34, and 36 is set to 20 ppm/° C., and the thermal expansion coefficient of the second insulating layers 42 and 44 is set to 10 ppm/° C.

When such a wiring substrate 10B of the comparative example is exposed to a high-temperature environment of approximately 260° C. when mounting the semiconductor chip 70, the core substrate 20 is most likely to expand compared to the first insulating layers 32, 34, and 36 and the second insulating layers 42 and 44. In this case, the core substrate 20 is thicker than the first insulating layers 32, 34, and 36 and the second insulating layers 42 and 44. Accordingly, the core substrate 20 becomes dominant in terms of the thermal expansion in the wiring substrate 10B. Therefore, the expansion of the core substrate 20 is followed by expansion of the entire wiring substrate 10B. As a result, the pads P2 of the wiring substrate 10B may be displaced from the connection terminals 71 of the semiconductor chip 70.

Subsequently, when the temperature returns to room temperature, as illustrated in FIG. 16B, the wiring substrate 10B acts to return to its original state before the expansion. In this case, the core substrate 20 becomes dominant in terms of the thermal contraction of the wiring substrate 10B. Accordingly, the contraction of the core substrate 20 is followed by contraction of the entire wiring substrate 10B. Such thermal contraction applies internal stress to the solder layer 72 and the like and may cause cracking or breaking of the solder layer 72 and the like. This may lower the connection reliability between the semiconductor chip 70 and the wiring substrate 10B.

As described above, even when the thermal expansion coefficient of the second insulating layers 42 and 44 is set to be lower than the thermal expansion coefficient of the first insulating layers 32, 34, and 36, if the thermal expansion coefficient of the second insulating layers 42 and 44 is lower than the thermal expansion coefficient of the core substrate 20, the connection reliability will be lowered. Therefore, in order to improve the connection reliability with the semiconductor chip 70, it is important that the thermal expansion coefficient of the second insulating layers 42 and 44 be set lower than the thermal expansion coefficient of the first insulating layers 32, 34, and 36 and higher than the thermal expansion coefficient of the core substrate 20, as in the wiring substrate 10.

### Warpage Simulations

Warpage of the wiring substrate 10 illustrated in FIG. 1 and warpage of the wiring substrate 10A of a conventional example illustrated in FIGS. 14A and 14B were simulated.

### Simulation Conditions

The exemplary wiring substrates 10 were square in plan view and had a size of 55 mm×55 mm. In these wiring substrates 10, the core substrate 20 had a thickness of 1.2 mm, each of the first insulating layers 32, 34, and 36 had a thickness of 30 μm, each of the second insulating layers 42 and 44 had a thickness of 10 μm, and each of the third insulating layers 52 and 54 had a thickness of 30 μm. Further, in these wiring substrates 10, the core substrate 20 had a thermal expansion coefficient of 7 ppm/° C., the first insulating layers 32, 34, and 36 had a thermal expansion coefficient of 20 ppm/° C., and the third insulating layers 52 and 54 had a thermal expansion coefficient of 20 ppm/° C. Warpage of such wiring substrates 10 were simulated when the thermal expansion coefficient of the second insulating layers 42 and 44 was changed to 18 ppm/° C. (Example 1), 12 ppm/° C. (Example 2), and 8 ppm/° C. (Example 3). In this manner, the thermal expansion coefficient of the second insulating layers 42 and 44 of Examples 1, 2, and 3 were set to be higher than the thermal expansion coefficient of the core substrate 20 and lower than the thermal expansion coefficient of the first insulating layers 32, 34, and 36 and the thermal expansion coefficient of the third insulating layers 52 and 54.

The wiring substrate 10A of the conventional example had the same structure as the exemplary wiring substrates 10 except that the thermal expansion coefficient of the second insulating layers 42 and 44 was 37 ppm/° C. In this manner, the thermal expansion coefficient of the second insulating layers 42 and 44 of the wiring substrate 10A of the conventional example was set to be higher than the thermal expansion coefficient of the core substrate 20, the thermal expansion coefficient of the first insulating layers 32, 34, and 36, and the thermal expansion coefficient of the third insulating layers 52 and 54. Warpage of such a wiring substrate 10A was simulated under the same condition as that of Examples.

### Simulation Results

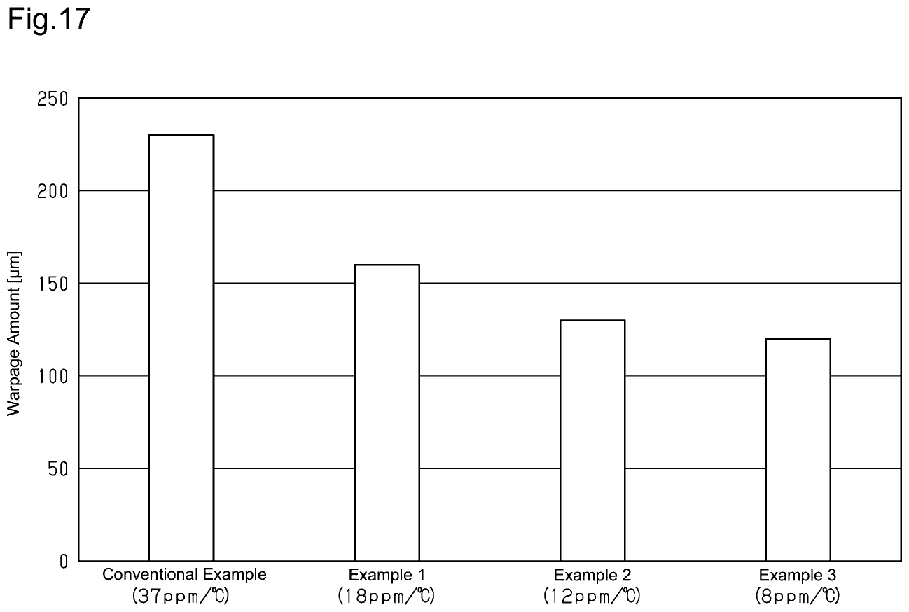

FIG. 17 indicates the results of warpage simulations. As indicated in FIG. 17, the wiring substrates 10 of Examples 1, 2, and 3 had a smaller amount of warpage than the conventional wiring substrate 10A. Also, as apparent from the results of Examples 1, 2, and 3, the amount of warpage decreased as the thermal expansion coefficient of the second insulating layers 42 and 44 decreased.

This indicates that warping of the wiring substrate 10 may be reduced by setting the thermal expansion coefficient of the second insulating layers 42 and 44 to be higher than the thermal expansion coefficient of the core substrate 20 and lower than the thermal expansion coefficient of the first insulating layers 32, 34, and 36 and the thermal expansion coefficient of the third insulating layers 52 and 54. Furthermore, warping of the wiring substrate 10 may be reduced effectively when the thermal expansion coefficient of the second insulating layers 42 and 44 is set relatively close to the thermal expansion coefficient of the core substrate 20.

### Advantages of Wiring Substrate 10 and Semiconductor Device 1

The wiring substrate 10 and the semiconductor device 1 have the following advantages.
(1) The wiring substrate 10 includes the core substrate 20, the first wiring structure 30 formed on the upper surface of the core substrate 20, and the second wiring structure 40 formed on the upper surface of the first wiring structure 30. The first wiring structure 30 includes a structure in which first wiring layers 31, 33, and 35 and first insulating layers 32, 34, and 36 are stacked. The second wiring structure 40 includes a structure in which second wiring layers 41, 43, and 45 and the second insulating layers 42 and 44 are stacked. The second wiring structure 40 has a higher density than the first wiring structure 30. The second insulating layers 42 and 44 have a thermal expansion coefficient higher than the thermal expansion coefficient of the core substrate 20 and lower than the thermal expansion coefficient of the first insulating layers 32, 34, and 36.

With this structure, the thermal expansion coefficient of the second insulating layer 42, 44 is closer to the thermal expansion coefficient of the core substrate 20 than the thermal expansion coefficient of the first insulating layers 32, 34, and 36 is. This effectively reduces warping of the wiring substrate 10 when the wiring substrate 10 is exposed to a high-temperature environment. As a result, the stress applied to the second wiring layers 41, 43, and 45 and the via wirings V1 and V2 of the second wiring structure 40 is reduced, thereby effectively avoiding formation of cracks or breakage in the second wiring layers 41, 43, and 45 and the via wirings V1 and V2. Further, when the semiconductor chip 70 is mounted and then the temperature returns to room temperature, the stress applied to the solder layer 72 and the like is reduced, thereby effectively avoiding formation of cracks or breakage in the solder layer 72 and the like. In this manner, the connection reliability between the wiring substrate 10 with the semiconductor chip 70 is maintained. In other words, the connection reliability between the wiring substrate 10 with the semiconductor chip 70 is improved compared to that of the conventional wiring substrate 10A.
(2) The wiring substrate 10 further includes the third wiring structure 50 formed on the lower surface of the core substrate 20. The third wiring structure 50 includes a structure in which third wiring layers 51, 53, and 55 and third insulating layers 52 and 54 are stacked. The wiring density of the second wiring structure 40 is higher than the wiring density of the third wiring structure 50. The thermal expansion coefficient of the second insulating layers 42 and 44 is lower than the thermal expansion coefficient of the third insulating layers 52 and 54.

With this structure, the thermal expansion coefficient of the second insulating layers 42 and 44 is closer to the thermal expansion coefficient of the core substrate 20 than the thermal expansion coefficient of the third insulating layers 52 and 54 is. This effectively reduces warping of the wiring substrate 10 when the wiring substrate 10 is exposed to a high-temperature environment. As a result, formation of cracks or breakage in the second wiring layers 41, 43, and 45 and the via wirings V1 and V2 of the second wiring structure 40 are avoided effectively. Further, formation of cracks or breakage in the solder layer 72 are avoided effectively. This improves the connection reliability between the wiring substrate 10 and the semiconductor chip 70.
(3) The first insulating layers 32, 34, and 36 contain the first filler F1. The second insulating layers 42 and 44 contain the second filler F2. The average particle diameter of the second filler F2 is smaller than the average particle diameter of the first filler F1. Thus, the fine through holes 42X and 44X may be readily formed in the second insulating layers 42 and 44, which contain the second filler F2 having a relatively small average particle diameter. This facilitates formation of fine wiring in the second wiring structure 40, which includes the second insulating layers 42 and 44.
(4) The content rate of the second filler F2 is higher than the content rate of the first filler F1. Therefore, the thermal expansion coefficient of the second insulating layers 42 and 44 containing the second filler F2 is readily adjusted to be lower than the thermal expansion coefficient of the first insulating layers 32, 34, and 36 containing the first filler F1.
(5) The second insulating layers 42 and 44 include a non-photosensitive resin as a main component. Therefore, the thermal expansion coefficient of the second insulating layers 42 and 44 is readily adjusted as compared to when the second insulating layers 42 and 44 include a photosensitive resin as a main component.
(6) If the thermal expansion coefficient of the core substrate 20 is set to be lower than or equal to the thermal expansion coefficient of the semiconductor chip 70, the difference in thermal expansion coefficient between the core substrate 20 and the first insulating layers 32, 34, and 36, and the difference in thermal expansion coefficient between the core substrate 20 and the third insulating layers 52 and 54 will increase. In this case, when the wiring substrate 10 is exposed to a high-temperature environment, the core substrate 20 will not expand as much as the first insulating layers 32, 34, and 36 and the third insulating layers 52 and 54. This may produce internal stress in the core substrate 20 and cause cracks or breakage in the core substrate 20.

In contrast, in the semiconductor device 1 of the present embodiment, the thermal expansion coefficient of the core substrate 20 is set to be higher than the thermal expansion coefficient of the semiconductor chip 70. With this structure, the thermal expansion coefficient of the core substrate 20 is closer to that of the first insulating layers 32, 34, and 36 and that of the third insulating layers 52 and 54 as compared when the thermal expansion coefficient of the core substrate 20 is set to be lower than or equal to that of the semiconductor chip 70. This reduces the internal stress produced in the core substrate 20, thereby avoiding formation of cracks or breakage in the core substrate 20.

### MODIFIED EXAMPLES

The above embodiment may be modified as described below. The above embodiment and the following modifications may be combined as long as the combined modifications remain technically consistent with each other.

In the above embodiment, the via wirings extending through the first insulating layer 36, which is the uppermost layer of the first wiring structure 30, in the thickness-wise direction are formed continuously and integrally with the second wiring layer 41, which is the lowermost layer of the second wiring structure 40. Instead, the wiring substrate 10 may be modified as follows.

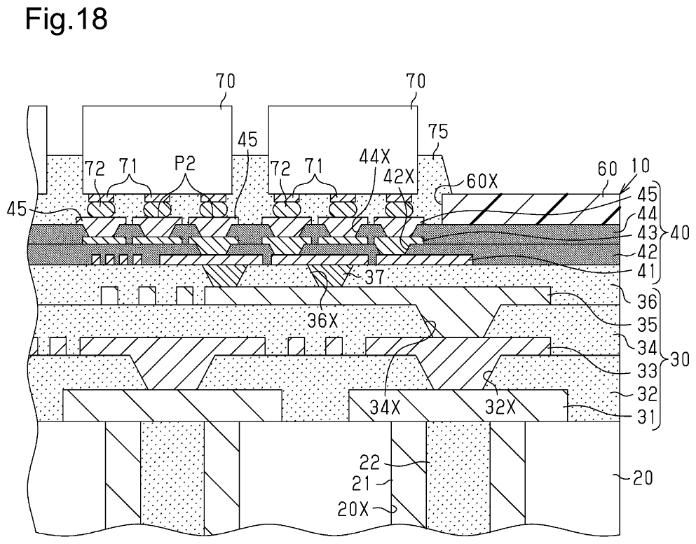

As illustrated in FIG. 18, for example, via wirings 37 extending through the first insulating layer 36, which is the uppermost layer of the first wiring structure 30, in the thickness-wise direction may be formed separate from the second wiring layer 41, which is the lowermost layer of the second wiring structure 40. For example, the through holes 36X of the first insulating layer 36 are filled with the via wirings 37. The upper surface of the via wirings 37 is exposed from the upper surface of the first insulating layer 36. The upper surface of the via wirings 37 is, for example, flush with the upper surface of the first insulating layer 36. The upper surface of the via wirings 37 and the upper surface of the first insulating layer 36 are, for example, polished surfaces. In the first wiring structure 30 of the present modified example, the via wirings 37 are the uppermost first wiring layer. The second wiring layer 41 of the present modified example is located on the upper surface of the via wirings 37 and the upper surface of the first insulating layer 36.

The number of layers, wiring layout, or the like of the second wiring layers and the second insulating layers in the second wiring structure 40 of the above embodiment may be modified in any manner.

In the above embodiment, the second insulating layers 42 and 44 include a non-photosensitive resin as a main component. However, the second insulating layers 42 and 44 may include, for example, a photosensitive resin as a main component.

The number of layers, wiring layout, or the like of the first wiring layers and the first insulating layers in the first wiring structure 30 of the above embodiment may be modified in any manner. For example, the first wiring structure 30 may be changed to a structure including a single first wiring layer and a single first insulating layer.

The number of layers, wiring layout, or the like of the third wiring layers and the third insulating layers in the third wiring structure 50 of the above embodiment may be modified in any manner. For example, the third wiring structure 50 may be changed to a structure including a single third wiring layer and a single third insulating layer.

In the above embodiment, the solder resist layers 60 and 61 are described as examples of protective insulating layers located at the outermost layers of the wiring substrate 10. However, the protective insulating layers may be formed from any type of various photosensitive insulating resins.

The solder resist layers 60 and 61 of the above embodiment may be omitted.

In the semiconductor device 1 of the above embodiment, the semiconductor chips 70 are mounted on the wiring substrate 10. Instead, electronic components other than the semiconductor chips 70 may be mounted on the wiring substrate 10. Examples of such an electronic component may include a crystal oscillator or a chip component, such as a chip capacitor, a chip resistor, or a chip inductor.

Electronic components such as the semiconductor chip 70, a chip component, or a crystal oscillator may be mounted by any method, such as flip-chip mounting, wire bonding, solder bonding, or combination of these.

The through-electrodes 21 of the above embodiment may be changed to, for example, through-electrodes that completely fill the through holes 20X with a plating metal layer (e.g., Cu layer) or the like.

In the above embodiment, the present disclosure is embodied in a method for manufacturing a single substrate. Instead, the present disclosure may be embodied in a method for manufacturing a batch of substrates.

### CLAUSES

This disclosure further encompasses the following embodiments.
1. A method for manufacturing a wiring substrate, the method including:
preparing a core substrate;
forming a first wiring structure on an upper surface of the core substrate, the first wiring structure including one or more first wiring layers and one or more first insulating layers; and
forming a second wiring structure on an upper surface of the first wiring structure, the second wiring structure including a structure in which multiple second wiring layers and multiple second insulating layers are stacked, where
the second wiring structure has a wiring density higher than a wiring density of the first wiring structure, and
the multiple second insulating layers have a thermal expansion coefficient higher than a thermal expansion coefficient of the core substrate and lower than a thermal expansion coefficient of the one or more first insulating layers.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate, comprising:
a core substrate;
a first wiring structure located on an upper surface of the core substrate; and
a second wiring structure located on an upper surface of the first wiring structure, wherein
the first wiring structure includes one or more first wiring layers and one or more first insulating layers,
the second wiring structure includes a structure in which multiple second wiring layers and multiple second insulating layers are stacked,
the second wiring structure has a wiring density higher than a wiring density of the first wiring structure, and
the multiple second insulating layers have a thermal expansion coefficient higher than a thermal expansion coefficient of the core substrate and lower than a thermal expansion coefficient of the one or more first insulating layers.

2. The wiring substrate according to claim 1, further comprising:
a third wiring structure located on a lower surface of the core substrate, wherein
the third wiring structure includes one or more third wiring layers and one or more third insulating layer,
the wiring density of the second wiring structure is higher than a wiring density of the third wiring structure, and
the thermal expansion coefficient of the multiple second insulating layers is lower than a thermal expansion coefficient of the one or more third insulating layers.

3. The wiring substrate according to claim 1, wherein
the one or more first insulating layers contain a first filler,
the multiple second insulating layers contain a second filler, and
the second filler has an average particle diameter smaller than an average particle diameter of the first filler.

4. The wiring substrate according to claim 3, wherein the second filler has a content rate higher than a content rate of the first filler.

5. The wiring substrate according to claim 1, wherein
the one or more first insulating layers include a non-photosensitive resin as a main component, and
the multiple second insulating layers include a non-photosensitive resin as a main component.

6. The wiring substrate according to claim 1, wherein
each of the multiple second insulating layers has a thickness less than a thickness of each of the one or more first insulating layers, and
the thickness of each of the one or more first insulating layers is less than a thickness of the core substrate.

7. The wiring substrate according to claim 1, further comprising a solder resist layer located on an upper surface of the second wiring structure.

8. The wiring substrate according to claim 1, wherein
the one or more first wiring layers include an uppermost first wiring layer, and
the one or more first insulating layers include an uppermost first insulating layer,
the uppermost first wiring layer includes a via wiring extending through the uppermost first insulating layer in a thickness-wise direction, and
the via wiring has an upper surface flush with an upper surface of the uppermost insulating layer.

9. A semiconductor device, comprising:
the wiring substrate according to claim 1; and
a semiconductor chip mounted on an uppermost second wiring layer of the multiple second wiring layers,
wherein the thermal expansion coefficient of the core substrate is higher than a thermal expansion coefficient of the semiconductor chip.
